(19) United States
(12) Patent Application Publication
(10) Pub. No.: US 2022/0181582 A1
(43) Pub. Date: Jun. 9, 2022

(54) DISPLAY DEVICE, AND METHOD FOR MANUFACTURING DISPLAY DEVICE

(71) Applicant: SHARP KABUSHIKI KAISHA, Sakai City, Osaka (JP)

(72) Inventors: Shota NOMIYAMA, Sakai City, Osaka (JP); AKIHIRO MATSUI, Sakai City, Osaka (JP); JUMPEI TAKAHASHI, Sakai City, Osaka (JP); TAKESHI HIRASE, Sakai City, Osaka (JP); YOSHINOBU MIYAMOTO, Sakai City, Osaka (JP); TOHRU SENOO, Sakai City, Osaka (JP)

(21) Appl. No.: 17/440,752

(22) PCT Filed: Mar. 28, 2019
(86) PCT No.: PCT/JP2019/013852

§ 371 Date: Sep. 17, 2021

(51) Int. Cl. H01L 51/52; H01L 27/32; H01L 51/56

(52) U.S. Cl. CPC H01L 51/5253; H01L 2227/323; H01L 51/56; H01L 27/3244

(57) ABSTRACT

A display device includes a sealing layer including a lower insulating film, an organic insulating film including an ink material cured, and an upper insulating film. The lower insulating film includes a first lower insulating film and a second lower insulating film layered on the first lower insulating film and having a higher lyophilicity with respect to the ink material than a lyophilicity of the first lower insulating film. The first lower insulating film is exposed from the second lower insulating film between a first bank and a second bank in a plan view and an end portion of the exposed first lower insulating film is provided on a side opposite to a display region with respect to the second bank, and an end portion of the second lower insulating film is provided between the first bank and the second bank in a plan view.

### TECHNICAL FIELD

The disclosure relates to a display device and a method for manufacturing a display device.

### BACKGROUND ART

A resin of an organic layer included in a sealing film for sealing an organic EL element to prevent infiltration of moisture or oxygen into the organic EL element is liquid and has a wet-spreading characteristic. Thus, for example, PTL 1 discloses that in an organic EL panel including an organic EL element formed of an organic film including a light-emitting layer, a flow of the resin that seals the organic EL element is stopped by forming a plurality of banks surrounding the organic EL element in multiple layers.

### CITATION LIST

### Patent Literature

PTL 1: JP 2012-253036 A (published on Dec. 20, 2012)

### SUMMARY

### Technical Problem

However, there is a problem in that an ink material constituting an organic insulating film formed over a lower insulating film of the sealing layer formed to cover the plurality of banks that surround the organic EL element in multiple layers may be applied beyond a bank of the outermost periphery of the plurality of banks.

An aspect of the disclosure is directed to providing a display device in which an ink material constituting an organic insulating film of a sealing layer that seals a light-emitting element layer can be appropriately applied, and a method for manufacturing the display device.

### Solution to Problem

A display device according to the disclosure includes: a substrate; a thin film transistor layer having a thin film transistor and an inorganic insulating film; a light-emitting element layer; and a sealing layer, the substrate, the thin film transistor layer, the light-emitting element layer, and the sealing layer being layered in this order, the sealing layer including a lower insulating film, an organic insulating film including an ink material cured, and an upper insulating film, the display device including a display region provided with pixels, and a frame region surrounding the display region, wherein a first bank defining an end portion of the organic insulating film and a second bank surrounding the first bank are formed in the frame region, the lower insulating film includes a first lower insulating film covering the light-emitting element layer and the first bank, and a second lower insulating film layered on the first lower insulating film and having a higher lyophilicity with respect to the ink material than a lyophilicity of the first lower insulating film, the first lower insulating film is exposed from the second lower insulating film between the first bank and the second bank in a plan view and an end portion of the exposed first lower insulating film is provided on a side opposite to the display region with respect to the second bank, and an end portion of the second lower insulating film is provided between the first bank and the second bank in a plan view.

A method for manufacturing a display device according to the disclosure is a method for manufacturing a display device, the display device including a substrate; a thin film transistor layer having a thin film transistor and an inorganic insulating film; a light-emitting element layer; and a sealing layer, the substrate, the thin film transistor layer, the light-emitting element layer, and the sealing layer being layered in this order, the sealing layer including a lower insulating film, an organic insulating film including a cured ink material, and an upper insulating film, the display device including a display region provided with pixels, and a frame region surrounding the display region, the lower insulating film including a first lower insulating film having a liquid repellency with respect to the ink material, and a second lower insulating film having a lyophilicity with respect to the ink material, the method comprising: a bank forming step of forming a first bank defining an end portion of the organic insulating film and a second bank surrounding the first bank in the frame region; a first lower insulating film forming step of forming the first lower insulating film covering the light-emitting element layer, the first bank, and the second bank; and a second lower insulating film forming step of forming the second lower insulating film on the first lower insulating film, an end portion of the second lower insulating film being provided between the first bank and the second bank.

### Advantageous Effects Disclosure

According to an aspect of the disclosure, it is possible appropriately apply an ink material constituting an organic insulating film of a sealing layer that seals a light-emitting element layer.

### BRIEF DESCRIPTION OF DRAWINGS

FIG. 1 is a plan view schematically illustrating an overall configuration of main portions of a display device according to a first embodiment.

FIG. 2 is a cross-sectional view taken along a plane AA illustrated in FIG. 1.

FIG. 3 is a plan view schematically illustrating a relationship between a lower insulating film, a first bank, and a second bank of the display device.

FIG. 4 is a plan view schematically illustrating a relationship between a lower insulating film, a first bank, and a second bank according to a comparative example.

FIG. 5 is a plan view schematically illustrating a relationship between a lower insulating film, a first bank, and a second bank of a display device according to a second embodiment.

FIG. 6 is an enlarged cross-sectional view schematically illustrating a relationship between the lower insulating film, the first bank, and the second bank.

### DESCRIPTION OF EMBODIMENTS

### First Embodiment

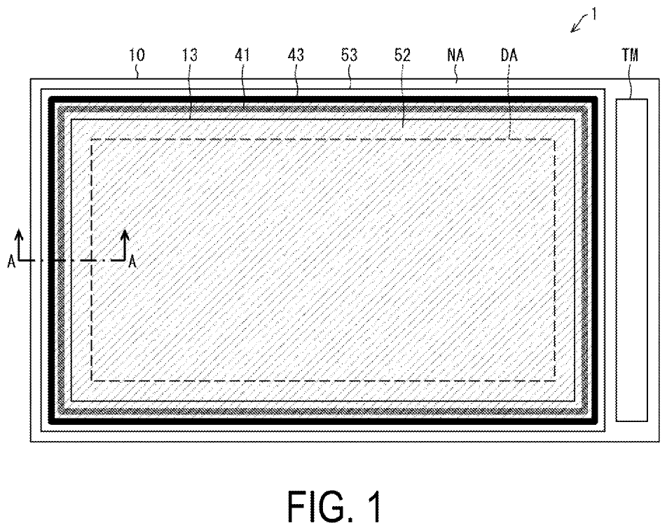

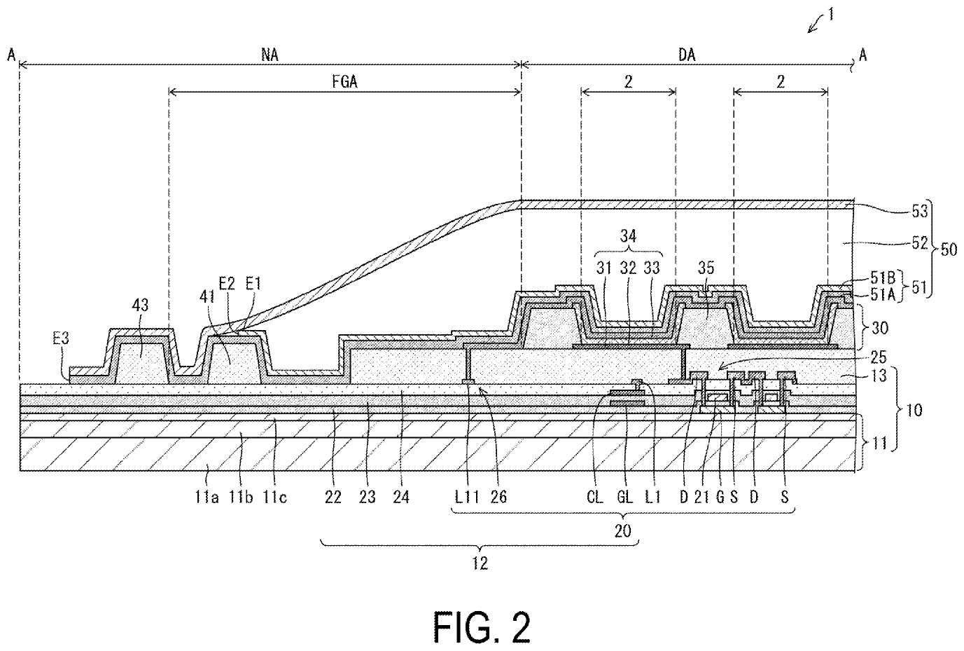

FIG. 1 is a plan view schematically illustrating an overall configuration of main portions of a display device 1 according to a first embodiment. FIG. 2 is a cross-sectional view taken along a plane AA illustrated in FIG. 1. In the display device 1 according to the first embodiment, a second bank 43 surrounds a first bank 41 such that the second bank 43 is positioned outside the first bank 41. An organic insulating film 52 is provided inside the first bank 41.

FIG. 2 illustrates an example of a case in which the display device 1 is an organic EL display device including, as an electro-optical element, an organic light emitting diode (OLED) element 34 referred to as an organic EL element.

The display device 1 includes, for example, a thin film transistor (TFT) substrate as a circuit substrate 10 and also includes a light-emitting element layer 30 (OLED element portion) as an electro-optical element layer.

### Circuit Substrate 10

The circuit substrate 10 illustrated in FIG. 2 includes a substrate 11 having an insulating property, a thin film transistor layer 12 provided on the substrate 11, and a flattening layer 13 that covers a circuit portion 20 in the thin film transistor layer 12.

As illustrated in FIG. 2, for example, the substrate 11 may be a layered film including a lower face film 11a, a resin layer 11b, and a barrier layer 11c provided in this order, or may be a glass substrate, a plastic substrate, or a plastic film.

Examples of resin used for the resin layer 11b, the plastic substrate, or the plastic film include a polyimide, polyethylene naphthalate, a polyamide and the like.

The barrier layer 11c is a layer for preventing moisture and impurities from reaching the thin film transistor layer 12 or the light-emitting element layer 30. The barrier layer 11c is provided over the whole surface of the resin layer 11b, such that the surface of the resin layer 11b is not exposed. The barrier layer 11c can be formed of, for example, a silicon nitride (SiNx) film, a silicon oxide (SiOx) film, or a layered film thereof formed using Chemical Vapor Deposition (CVD).

In a case where the display device 1 is a flexible device, the lower face film 11a is bonded to a lower face of the resin layer 11b with an adhesive layer (not illustrated), for example, interposed therebetween, so that even when the resin layer 11b is extremely thin, the display device 1 having sufficient strength is manufactured. A plastic film formed from a flexible resin is used as the lower face film 11a. Examples of the flexible resin include polyethylene terephthalate, polyethylene naphthalate, a polyimide, a polycarbonate, and polyethylene.

The thin film transistor layer 12 is a circuit layer including the circuit portion 20 in which a thin film transistor 25 that drives an electro-optical element (OLED element 34 in the example illustrated in FIG. 2) and a plurality of wiring lines are formed, and inorganic insulating films 22, 23, and 24 that protect the wiring lines in the circuit portion 20 and electrodes (gate electrode G, source electrode S, and drain electrode D) in the thin film transistor 25.

The wiring lines include, for example, wiring lines such as a plurality of gate wiring lines GL, a plurality of source wiring lines (not illustrated), a plurality of capacitance wiring lines CL, a plurality of high level power source lines L1, a plurality of low level power source lines (not illustrated), and a plurality of second electrode connecting wiring lines L11. The inorganic insulating films 22, 23, and 24 are formed so as to cover the whole surface of the substrate 11.

The thin film transistor layer 12 has a configuration in which a semiconductor layer 21 formed into a plurality of island shapes, the inorganic insulating film 22, a first wiring line layer, the inorganic insulating film 23, a second wiring line layer, the inorganic insulating film 24, and a third wiring line layer are layered in this order. A terminal portion TM (see FIG. 1) including a plurality of terminals for external connection is provided in an end portion of the thin film transistor layer 12.

The first wiring line layer includes, for example, the plurality of gate electrodes G, the plurality of gate wiring lines GL connected to the plurality of gate electrodes G, and the plurality of low level power source lines (not illustrated). The second wiring line layer includes, for example, the plurality of capacitance wiring lines CL. The third wiring line layer includes, for example, the plurality of source electrodes S, the plurality of source wiring lines (not illustrated) connected to the plurality of source electrodes S, the plurality of drain electrodes D, the plurality of high level power source lines L1, and the plurality of second electrode connecting wiring lines L11 connected to a second electrode 33 of the OLED element 34. The gate wiring line GL and the source wiring line intersect each other orthogonally in a plan view.

The flattening layer 13 is provided on the thin film transistor layer 12 so as to cover the third wiring line layer. As a result, the flattening layer 13 levels steps on the thin film transistor 25 and the third wiring line layer.

The semiconductor layer 21, the gate electrode G, the inorganic insulating film 22, the source electrode S, and the drain electrode D constitute the thin film transistor 25.

The source electrode S and the drain electrode D are each connected to the semiconductor layer 21 with a contact hole provided in the inorganic insulating films 22, 23, and 24 interposed therebetween. The source electrode S is also connected to a source wiring line, which is not illustrated. The drain electrode D is connected to a first electrode 31 of the OLED element 34 with a contact hole provided in the flattening layer 13 interposed therebetween. The capacitance wiring lines CL are each connected to each of the high level power source lines L1 with a contact hole provided in the inorganic insulating film 24 interposed therebetween.

Note that FIG. 2 illustrates an example of a case in which the thin film transistor 25 has a top gate structure. However, the thin film transistor 25 may have a bottom gate structure.

The display device 1 includes a display region DA (region overlapping with the electro-optical element layer in a plan view) provided with the electro-optical element and a frame region NA (frame region, region that does not overlap with the electro-optical element layer in a plan view), the frame region NA being a peripheral region surrounding the periphery of the display region DA.

In the display device 1 illustrated in FIG. 2, the display region DA is a region (region overlapping with the light-emitting element layer 30) provided with the OLED element 34 and a pixel region provided with a plurality of pixels 2. The frame region NA is a region that does not overlap with the light-emitting element layer 30.

As illustrated in FIG. 1 and FIG. 2, the circuit portion 20 and the flattening layer 13 are provided from the display region DA to the frame region NA. As illustrated in FIG. 1, the terminal portion TM is provided in a part of the frame region NA. The gate wiring line GL and the source wiring line are each connected to a terminal (not illustrated) in the terminal portion TM via a lead wiring line (not illustrated). The frame region NA is provided with a lead-out wiring line, a second electrode connecting portion 26 that connects the second electrode connecting wiring line L11 to the second electrode 33 extending from the display region DA, and the like. Note that, a source wiring line may be used as the second electrode connecting wiring line L11.

The semiconductor layer 21 is formed of, for example, low temperature polysilicon (LTPS) or an oxide semiconductor. The inorganic insulating film 22 can be formed of, for example, a silicon oxide (SiOx) film or a silicon nitride (SiNx) film, or a layered film of these, formed by using a CVD method. The first wiring line layer, the second wiring line layer, the third wiring line layer, and the terminal portion TM are constituted by a single-layer film or a layered film of a metal such as aluminum (Al), tungsten (W), molybdenum (Mo), tantalum (Ta), chromium (Cr), titanium (Ti), or copper (Cu), for example. The flattening layer 13 can be formed of a photosensitive resin such as polyimide resin and acrylic resin, for example.

### Light-Emitting Element Layer 30

As illustrated in FIG. 2, the light-emitting element layer 30 includes the first electrode 31, an organic EL layer 32 formed on the first electrode 31 and composed of an organic layer including at least a light-emitting layer, the second electrode 33 formed on the organic EL layer 32, and an edge cover 35.

The first electrode 31, the organic EL layer 32, and the second electrode 33 constitute the OLED element 34 constituting each of the pixels 2. Layers between the first electrode 31 and the second electrode 33 are collectively referred to as the organic EL layer 32 in the present embodiment.

The first electrode 31 is formed on the flattening layer 13 in the display region DA. The first electrode 31 injects (supplies) holes into the organic EL layer 32, while the second electrode 33 injects electrons into the organic EL layer 32.

The first electrode 31 is a pattern electrode (for example, a pattern anode) formed into an island-shaped pattern for each of the pixels 2. Meanwhile, the second electrode 33 is a solid-like common electrode (for example, a common cathode) provided in common for each of the pixels 2.

The first electrodes 31 are electrically connected to the thin film transistor 25 with a contact hole formed in the flattening layer 13 in each of the pixels 2 interposed therebetween. The second electrode 33 is electrically connected to the second electrode connecting wiring line L11 in the second electrode connecting portion 26.

The edge cover 35 is provided in, for example, a lattice pattern in a plan view so as to cover a peripheral portion (namely, each edge portion) of the first electrode 31. The edge cover 35 prevents a short-circuit with the second electrode 33 due to a concentration of electrodes, the thinned organic EL layer 32, or the like at the peripheral portion of the first electrode 31. The edge cover 35 also functions as a pixel separation layer that separates the pixels 2 (OLED elements 34) so as to prevent a current from leaking to the neighboring pixel 2 (OLED element 34). A photosensitive resin may be used for the edge cover 35.

A transparent conductive film such as indium tin oxide (ITO) or indium zinc oxide (IZO), or a thin film of a metal such as gold (Au), platinum (Pt), or nickel (Ni) is used as the first electrode 31, for example. To inject electrons into the light-emitting layer, a metal with a small work function, such as lithium (Li), cerium (Ce), barium (Ba), and aluminum (Al), or an alloy containing these metals, such as a magnesium alloy (MgAg or the like), an aluminum alloy (AlLi, AlCa, AlMg, or the like) can be used as the second electrode 33.

### First Bank 41 and Second Bank 43

As illustrated in FIG. 1 and FIG. 2, the frame region NA includes the first bank 41 and the second bank 43 such that the first bank 41 and the second bank 43 surround the flattening layer 13 provided with the OLED element 34, and is provided with a dam portion that holds back the ink material used for the organic insulating film 52 by stopping a flow of the ink material.

The first bank 41 is formed in a frame shape formed of a continuous line so as to surround the flattening layer 13 provided with the OLED element 34. The second bank 43 is formed in a frame shape formed of a continuous line so as to surround the first bank 41, outside the first bank 41.

The first bank 41 and the second bank 43 are organic layer stoppers that define an edge of the organic insulating film 52 by holding back the ink material used for the organic insulating film 52 (in other words, by holding back the organic insulating film 52).

The first bank 41 and the second bank 43 are formed of the same material in the same layer as the flattening layer 13, for example. In addition, the first bank 41 and the second bank 43 may be formed of the same material in the same layer as the edge cover 35, or may be formed of a laminate of the material of the flattening layer 13 and the material of the edge cover 35.

### Sealing Layer 50

The sealing layer 50 is a thin film encapsulation (TFE) layer, and includes the organic insulating film 52, and the lower insulating film 51 and the upper insulating film 53 that sandwich the organic insulating film 52. The lower insulating film 51 and the upper insulating film 53 are provided to overlap with each other in a plan view so as to seal the organic insulating film 52 therebetween.

The lower insulating film 51 and the upper insulating film 53 have a moisture-proof function to inhibit infiltration of moisture, and function as barrier layers to inhibit deterioration of electro-optical elements (the OLED elements 34 in the example illustrated in FIG. 2) by moisture or oxygen.

The organic insulating film 52 is used as a buffer layer, which relieves stress in the lower insulating film 51 and the upper insulating film 53 in which film stress is large, performs leveling and filling of pinholes by burying step portions and foreign material on the surface of the light-emitting element layer 30 being the electro-optical element layer, and further, prevents occurrence of cracks in the upper insulating film 53 when the upper insulating film 53 is layered, by leveling an underlying layer of the upper insulating film 53.

The upper insulating film 53 may be made of a silicon oxide film, a silicon nitride film, or a silicon oxynitride film, or a layered film thereof, formed using CVD, for example.

The organic insulating film 52 is a light-transmissive organic insulating film thicker than the lower insulating film 51 and the upper insulating film 53. The organic insulating film 52 is formed by, for example, applying the ink material (liquid organic material) to a region surrounded by the first bank 41 on the lower insulating film 51 using an ink-jet method or the like, and curing the ink material with UV. Examples of the organic material include a photosensitive resin, such as an acrylic resin, an epoxy resin, and a silicone resin.

Note that, a cover body (not illustrated) may be provided on the sealing layer 50 with an adhesive layer (not illustrated) interposed therebetween.

The cover body is a function layer having at least one of a protection function, an optical compensation function, or a touch sensor function. The cover body may be a protection film functioning as a support body when a carrier substrate such as a glass substrate is peeled, may be a hard coat layer such as a hard coat film, and may be a functional film such as a polarizing film or a touch sensor film.

### Lower Insulating Film 51

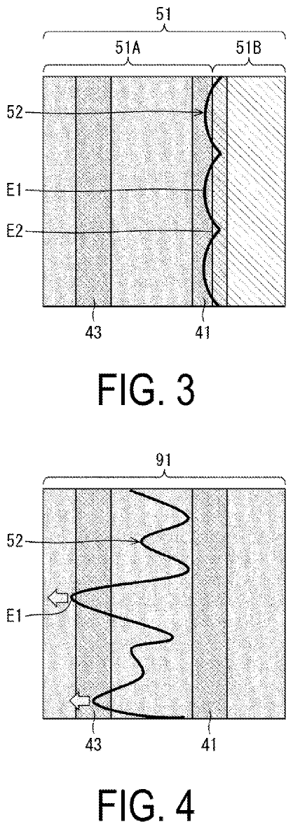

FIG. 3 is a plan view schematically illustrating a relationship between the lower insulating film 51, the first bank 41, and the second bank 42 of the display device 1.

The lower insulating film 51 according to the present embodiment includes a first lower insulating film 51A provided so as to cover the light-emitting element layer 30 and the first bank 41, and a second lower insulating film 51B layered on the first lower insulating film 51A. The first lower insulating film 51A has a liquid repellency with respect to the ink material of the organic insulating film 52. The second lower insulating film 51B is more lyophilic with respect to the ink material of the organic insulating film 52 than the first lower insulating film 51A. In a plan view, the first lower insulating film 51A is exposed from the second lower insulating film 51B between the first bank 41 and the second bank 43, and an end portion E3 of the exposed first lower insulating film 51A is provided on a side opposite to the display region DA with respect to the second bank 43. The end portion E2 of the second lower insulating film 51B is provided above the first bank 41 in a plan view.

A contact angle of the first lower insulating film 51A is 18° or greater. A contact angle of the second lower insulating film 51B is 5° or less. The first lower insulating film 51A includes SiN. The second lower insulating film 51B includes at least one of SiO, SiCN, SiOC, or SiOCN.

The lower insulating film 51 and the upper insulating film 53 are preferably inorganic insulating films. The organic insulating film 52 includes at least one of an acrylic resin, an epoxy resin, or a silicone resin.

The thickness of each of the first lower insulating film 51A and the second lower insulating film 51B is preferably 1 nm or greater and 10 nm or less.

In this manner, if the first lower insulating film 51A and the second lower insulating film 51B each having a mutually different wettability are formed on the first bank 41, when the end portion E1 of the ink material of the organic insulating film 52 reaches the end portion E2 of the second lower insulating film 51B at the time of forming the organic insulating film 52, the end portion E2 at which the wettability changes, the end portion E1 of the ink material spreads out laterally, so that the edge of the end portion E1 is smoothed as illustrated in FIG. 3. This makes it possible to suppress local formation of the end portion E1 of the ink material of the organic insulating film 52 beyond the second bank 43.

FIG. 4 is a plan view schematically illustrating a relationship between a lower insulating film 91, the first bank 41, and the second bank 43 according to a comparative example. When the lower insulating film 91 of the sealing layer is constituted by a film having a high wettability with respect to the ink material, as illustrated in FIG. 4, the end portion E1 of the ink material of the organic insulating film 52 is formed beyond the second bank 43, whereby there is a risk that poor reliability of the display device may be generated.

In contrast, in the present embodiment, the first lower insulating film 51A having a liquid repellency with respect to the ink material of the organic insulating film 52 and the second lower insulating film 51B having a lyophilicity with respect to the ink material are formed on the first bank 41, and thus, the organic insulating film 52 of the sealing layer 50 sealing the light-emitting element layer 30 is applied to an appropriate region.

### Method for Manufacturing Display Device 1

The display device 1 configured as described above is manufactured as follows. First, the first bank 41 that defines the end portion E1 of the organic insulating film 52 is formed on the inorganic insulating film 24 in the frame region NA. The first lower insulating film 51A is then formed so as to cover the light-emitting element layer 30 and the first bank 41. The first lower insulating film 51A can be formed by using a first mask having a first opening.

Next, the second bank 43 that surrounds the first bank 41 is formed on the inorganic insulating film 24. Thereafter, the second lower insulating film 51B is layered on the first lower insulating film 51A in such a manner that the end portion E3 of the first lower insulating film 51A is exposed from the second lower insulating film 51B and overlaps with the second bank 43 in a plan view, and the end portion E2 of the second lower insulating film 51B is disposed on the first bank 41 in a plan view. The second lower insulating film 51B can be formed by using a second mask having a second opening with a dimension different from that of the first opening. Alternatively, two types of insulating films each having a different wettability, that is, the first lower insulating films 51A and the second lower insulating films 51B, may be formed by using the same mask and changing the distance from the substrate.

Fluorine-plasma treatment may be performed between the step of forming the first lower insulating film 51A and the step of forming the second lower insulating film 51B to cause the surface of the first lower insulating film 51A to have a liquid repellency. In this case, two layers, that is, the first lower insulating film 51A and the second lower insulating film 51B can be formed of the same material.

### Second Embodiment

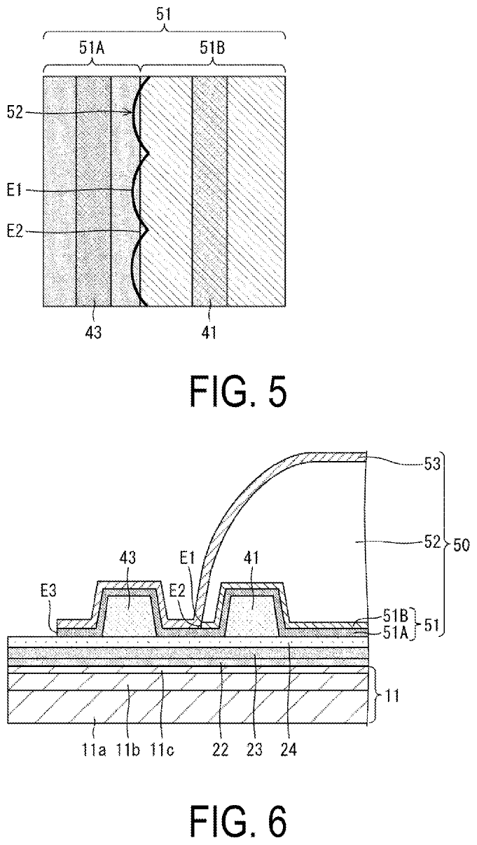

FIG. 5 is a plan view schematically illustrating a relationship between a lower insulating film, a first bank, and a second bank of a display device according to a second embodiment. FIG. 6 is an enlarged cross-sectional view schematically illustrating a relationship between the lower insulating film, the first bank, and the second bank. Constituent elements similar to the constituent elements described above are given the same reference numerals, and detailed descriptions thereof are not repeated.

The point different from the first embodiment described above is that the end portion E2 of the second lower insulating film 51B is disposed between the first bank 41 and the second bank 43, rather than overlapping with the first bank 41 as in the first embodiment.

In a plan view, the first lower insulating film 51A is exposed from the second lower insulating film 51B between the first bank 41 and the second bank 43, and the end portion E3 of the exposed first lower insulating film 51A is provided on a side opposite to the display region DA with respect to the second bank 43. The end portion E2 of the second lower insulating film 51B is provided between the first bank 41 and the second bank 42 in a plan view.

In this manner, if the first lower insulating film 51A and the second lower insulating film 51B each having a mutually different wettability are formed between the first bank 41 and the second bank 43, when the end portion E1 of the ink material of the organic insulating film 52 reaches the end portion E2 of the second lower insulating film 51B at the time of forming the organic insulating film 52, the end portion E2 at which the wettability changes, the end portion E1 of the ink material spreads out laterally and the edge of the end portion E1 is smoothed as illustrated in FIG. 5. This makes it possible to suppress local formation of the end portion E1 of the ink material of the organic insulating film 52 beyond the second bank 43.

### Supplement

A display device according to a first aspect is a display device including: a substrate; a thin film transistor layer having a thin film transistor and an inorganic insulating film; a light-emitting element layer; and a sealing layer, the substrate, the thin film transistor layer, the light-emitting element layer, and the sealing layer being layered in this order, the sealing layer including a lower insulating film, an organic insulating film including an ink material cured, and an upper insulating film, the display device including a display region provided with pixels, and a frame region surrounding the display region, wherein a first bank defining an end portion of the organic insulating film and a second bank surrounding the first bank are formed in the frame region, the lower insulating film includes a first lower insulating film covering the light-emitting element layer and the first bank, and a second lower insulating film layered on the first lower insulating film and having a higher lyophilicity with respect to the ink material than a lyophilicity of the first lower insulating film, the first lower insulating film is exposed from the second lower insulating film between the first bank and the second bank in a plan view and an end portion of the exposed first lower insulating film is provided on a side opposite to the display region with respect to the second bank, and an end portion of the second lower insulating film is provided between the first bank and the second bank in a plan view.

In a display device according to a second aspect, an end portion of the second lower insulating film overlaps with the first bank in a plan view.

In a display device according to a third aspect, a contact angle of the first lower insulating film is 18° or greater.

In a display device according to a fourth aspect, a contact angle of the second lower insulating film is 5° or less.

In a display device according to a fifth aspect, the first lower insulating film includes SiN, and the second lower insulating film includes at least one of SiO, SiCN, SiOC, or SiOCN.

In a display device according to a sixth aspect, the lower insulating film and the upper insulating film each are an inorganic insulating film.

In a display device according to a seventh aspect, the organic insulating film includes at least one of an acrylic resin, an epoxy resin, or a silicone resin.

A method for manufacturing a display device according to an eighth aspect is a method for manufacturing a display device, the display device including: a substrate; a thin film transistor layer having a thin film transistor and an inorganic insulating film; a light-emitting element layer; and a sealing layer, the substrate, the thin film transistor layer, the light-emitting element layer, and the sealing layer being layered in this order, the sealing layer including a lower insulating film, an organic insulating film including an ink material cured, and an upper insulating film, the display device including a display region provided with pixels, and a frame region surrounding the display region, the lower insulating film including a first lower insulating film having a liquid repellency with respect to the ink material, and a second lower insulating film having a lyophilicity with respect to the ink material, the method comprising: a bank forming step of forming a first bank defining an end portion of the organic insulating film and a second bank surrounding the first bank in the frame region; a first lower insulating film forming step of forming the first lower insulating film covering the light-emitting element layer, the first bank, and the second bank; and a second lower insulating film forming step of forming the second lower insulating film on the first lower insulating film, an end portion of the second lower insulating film being provided between the first bank and the second bank.

In a method for manufacturing a display device according to a ninth aspect, the first lower insulating film forming step forms the first lower insulating film by using a first mask having a first opening, and the second lower insulating film forming step forms the second lower insulating film by using a second mask having a second opening with a dimension different from a dimension of the first opening.

In a method for manufacturing a display device according to a tenth aspect, an end portion of the second lower insulating film overlaps with the first bank in a plan view.

In a method for manufacturing a display device according to an eleventh aspect, a contact angle of the first lower insulating film is 18° or greater.

In a method for manufacturing a display device according to a twelfth aspect, a contact angle of the second lower insulating film is 5° or less.

In a method for manufacturing a display device according to a thirteenth aspect, the first lower insulating film includes SiN and the second lower insulating film includes at least one of SiO, SiCN, SiOC, or SiOCN.

In a method for manufacturing a display device according to a fourteenth aspect, the lower insulating film and the upper insulating film each are an inorganic insulating film.

In a method for manufacturing a display device according to a fifteenth aspect, the organic insulating film includes at least one of an acrylic resin, an epoxy resin, or a silicone resin.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A display device comprising:
a substrate; a thin film transistor layer having a thin film transistor and an inorganic insulating film; a light-emitting element layer; and a sealing layer, the substrate, the thin film transistor layer, the light-emitting element layer, and the sealing layer being layered in this order,
the sealing layer including a lower insulating film, an organic insulating film including an ink material cured, and an upper insulating film,
the display device including a display region provided with pixels, and a frame region surrounding the display region,
wherein a first bank defining an end portion of the organic insulating film and a second bank surrounding the first bank are formed in the frame region,
the lower insulating film includes
a first lower insulating film covering the light-emitting element layer and the first bank, and
a second lower insulating film layered on the first lower insulating film and having a higher lyophilicity with respect to the ink material than a lyophilicity of the first lower insulating film,
the first lower insulating film is exposed from the second lower insulating film between the first bank and the second bank in a plan view and an end portion of the exposed first lower insulating film is provided on a side opposite to the display region with respect to the second bank, and
an end portion of the second lower insulating film is provided between the first bank and the second bank in a plan view.

2. The display device according to claim 1,
wherein an end portion of the second lower insulating film overlaps with the first bank in a plan view.

3. The display device according to claim 1,
wherein a contact angle of the first lower insulating film is 18° or greater.

4. The display device according to claim 1,
wherein a contact angle of the second lower insulating film is 5° or less.

5. The display device according to claim 1,
wherein the first lower insulating film includes SiN, and
the second lower insulating film includes at least one of SiO, SiCN, SiOC, or SiOCN.

6. The display device according to claim 1,
wherein the lower insulating film and the upper insulating film each are an inorganic insulating film.

7. The display device according to claim 1,
wherein the organic insulating film includes at least one of an acrylic resin, an epoxy resin, or a silicone resin.

8. A method for manufacturing a display device, the display device including: a substrate; a thin film transistor layer having a thin film transistor and an inorganic insulating film; a light-emitting element layer; and a sealing layer, the substrate, the thin film transistor layer, the light-emitting element layer, and the sealing layer being layered in this order, the sealing layer including a lower insulating film, an organic insulating film including an ink material cured, and an upper insulating film, the display device including a display region provided with pixels, and a frame region surrounding the display region,
the lower insulating film including a first lower insulating film having a liquid repellency with respect to the ink material, and a second lower insulating film having a lyophilicity with respect to the ink material,
the method comprising:
a bank forming step of forming a first bank defining an end portion of the organic insulating film and a second bank surrounding the first bank in the frame region;
a first lower insulating film forming step of forming the first lower insulating film covering the light-emitting element layer, the first bank, and the second bank; and
a second lower insulating film forming step of forming the second lower insulating film on the first lower insulating film, an end portion of the second lower insulating film being provided between the first bank and the second bank.

9. The method for manufacturing a display device according to claim 8,
wherein the first lower insulating film forming step forms the first lower insulating film by using a first mask having a first opening, and
the second lower insulating film forming step forms the second lower insulating film by using a second mask having a second opening with a dimension different from a dimension of the first opening.

10. The method for manufacturing a display device according to claim 8,
wherein an end portion of the second lower insulating film overlaps with the first bank in a plan view.

11. The method for manufacturing a display device according to claim 8,
wherein a contact angle of the first lower insulating film is 18° or greater.

12. The method for manufacturing a display device according to claim 8,
wherein a contact angle of the second lower insulating film is 5° or less.

13. The method for manufacturing a display device according to claim 8,
wherein the first lower insulating film includes SiN, and
the second lower insulating film includes at least one of SiO, SiCN, SiOC, or SiOCN.

14. The method for manufacturing a display device according to claim 8,
wherein the lower insulating film and the upper insulating film each are an inorganic insulating film.

15. The method for manufacturing a display device according to claim 8,
wherein the organic insulating film includes at least one of an acrylic resin, an epoxy resin, or a silicone resin.
